(19) United States
(12) Patent Application Publication
(10) Pub. No.: US 2013/0014977 A1
(43) Pub. Date: Jan. 17, 2013

(54) Plated Through Hole Void Detection in Printed Circuit Boards by Detecting Material Coupling to Exposed Laminate

(71) Applicants: Bruce John Chamberlin, Vestal, NY (US); Chang-Min Chu, Taipei (TW); Gao-Bin Hu, ShenZhen (CN); Joseph Kuczynski, Rochester, MN (US); Kaspar Ka Chung Tsang, Tung Chung (HK)

(72) Inventors: Bruce John Chamberlin, Vestal, NY (US); Chang-Min Chu, Taipei (TW); Gao-Bin Hu, ShenZhen (CN); Joseph Kuczynski, Rochester, MN (US); Kaspar Ka Chung Tsang, Tung Chung (HK)

(73) Assignee: INTERNATIONAL BUSINESS MACHINES CORPORATION, Armonk, NY (US)

(21) Appl. No.: 13/182,611

(22) Filed: Jul. 14, 2011

(51) Int. Cl. H05K 1/09; H05K 1/11; H05K 1/00; G01N 21/76; H05K 3/22

(52) U.S. Cl. 174/257; 436/172; 216/13; 174/258; 174/266; 422/52

(57) ABSTRACT

An approach is provided in detecting plated-through hole defects in printed circuit boards (PCBs). The printed circuit board is exposed to a modified-silane solution. The modified-silane solution has a luminescent moiety and the modified-silane solution binds to exposed glass within a glass fiber layer of the printed circuit board. Plated-through hole defects are identified in the printed circuit board by detecting a luminescence at a surface location of the printed circuit board. Each surface location where the luminescence is detected corresponds to one of the plated-through hole defects.

### BACKGROUND

The present invention relates to an approach that detects plated through hole voids in printed circuit boards using a luminescent component bound to a glass fiber layer of a circuit board.

Plated through hole voids are a known issue when manufacturing printed circuit boards (PCB). Plated through hole voids may potentially cause failure during assembly and are also considered as a long term reliability issue of the printed circuit boards. Current understanding of the phenomenon indicates that the voids typically form during composite copper plating before external circuitization. For example, voids may form if the copper plating solution was blocked by air bubbles, foreign material, or dry film resist residues. During that period, the entire PCB is virtually encased in copper. The only areas where laminate would be exposed is at a defect site where there is a void in the copper. This defect is difficult to detect using currently-available inspection capability or test equipment. The voids may not entirely encircle the hole wall and thus may not result in an electrical open thereby making it difficult to detect by an electrical method. In the subsequent card assembly and field application processes, these voids may become an intermittent open, or even a dead open, due to high thermal stress in the assembly process or temperature cycling during the application stage.

### BRIEF SUMMARY

An approach is provided in detecting plated-through hole defects in printed circuit boards (PCBs). The printed circuit board is exposed to a modified-silane solution. The modified-silane solution has a luminescent moiety and the modified-silane solution binds to exposed glass within a glass fiber layer of the printed circuit board. Plated-through hole defects are identified in the printed circuit board by detecting a luminescence at a surface location of the printed circuit board. Each surface location where the luminescence is detected corresponds to one of the plated-through hole defects.

The foregoing is a summary and thus contains, by necessity, simplifications, generalizations, and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION OF THE SEVERAL VIEWS OF THE DRAWINGS

The present invention may be better understood, and its numerous objects, features, and advantages made apparent to those skilled in the art by referencing the accompanying drawings, wherein:

FIG. 1 is a block diagram of a data processing system in which the methods described herein can be implemented;

FIG. 2 provides an extension of the information handling system environment shown in FIG. 1 to illustrate that the methods described herein can be performed on a wide variety of information handling systems which operate in a networked environment;

FIG. 3 is a diagram a printed circuit board (PCB) with a variety of plated through hole voids shown in various circuits on the PCB with the PCB being exposed to a modified silane solution that has a luminescence moiety;

FIG. 4 is a reaction scheme showing the modified silane reacting through trialkoxy groups with exposed silanols on the glass to form a siloxane which is polymerized to form a crosslinked plug in the plated-through hole (PTH) voids on the printed circuit board; and

FIG. 5 is a flowchart showing steps taken to detect voids in a PCB that has a been exposed to a modified silane solution with a luminescence moiety as shown in FIG. 3.

### DETAILED DESCRIPTION

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable signal medium may include a propagated data signal with computer readable program code embodied therein, for example, in baseband or as part of a carrier wave. Program code embodied on a computer readable medium may be transmitted using any appropriate medium, including but not limited to wireless, wireline, optical fiber cable, RF, etc., or any suitable combination of the foregoing. Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

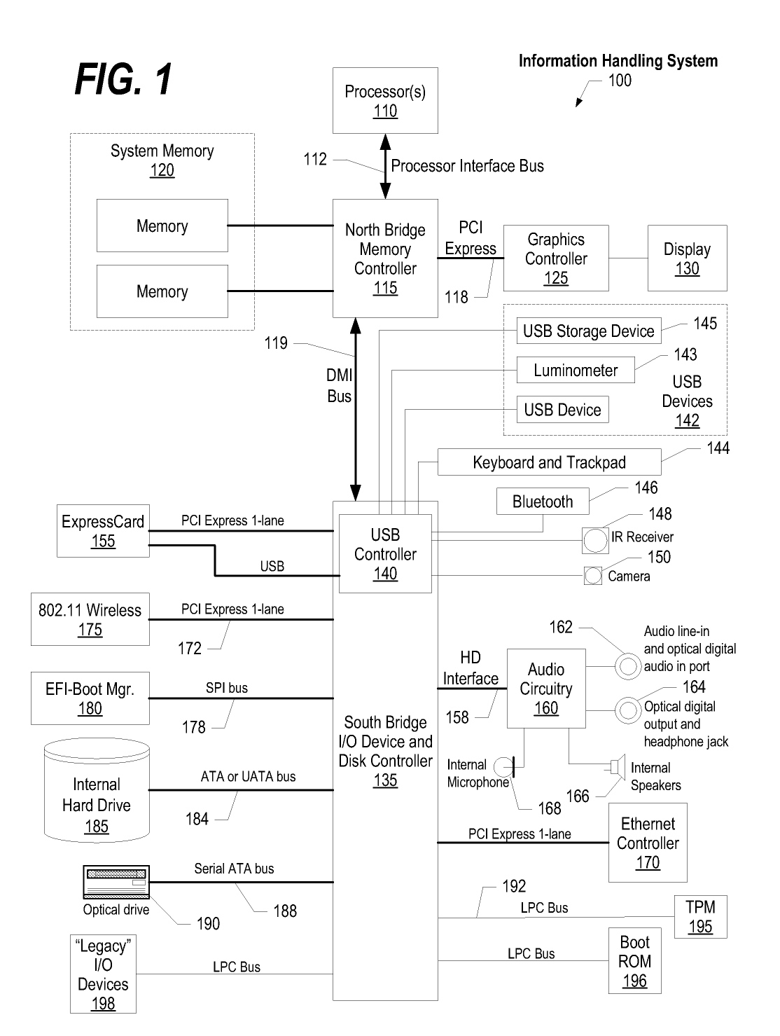

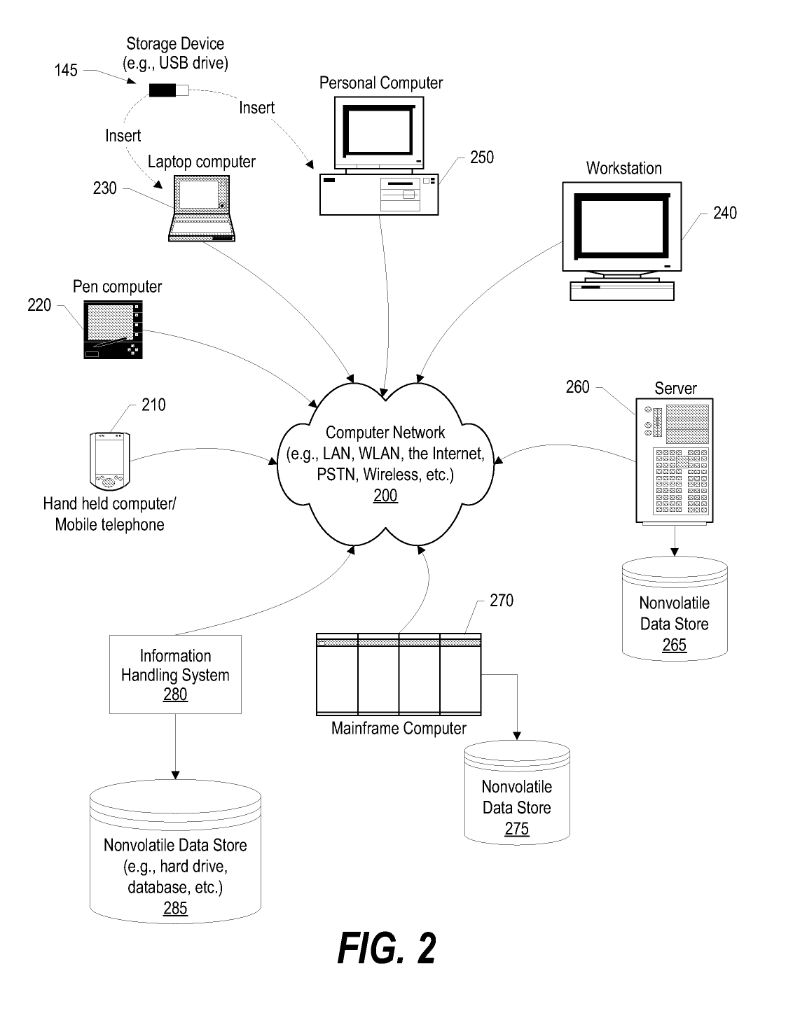

The following detailed description will generally follow the summary of the invention, as set forth above, further explaining and expanding the definitions of the various aspects and embodiments of the invention as necessary. To this end, this detailed description first sets forth a computing environment in FIG. 1 that is suitable to implement the software and/or hardware techniques associated with the invention. In addition, many of the components of an information system, such as motherboards, video cards, network cards, etc., include printed circuit boards. Such printed circuit boards can be manufactured using the invention described herein. A networked environment is illustrated in FIG. 2 as an extension of the basic computing environment, to emphasize that modern computing techniques can be performed across multiple discrete devices.

FIG. 1 illustrates information handling system 100, which is a simplified example of a computer system capable of performing the computing operations described herein. In addition, as noted above, many of the components of information handling system 100 include printed circuit boards. Such components include, but are not limited to motherboards, video cards, network cards, etc., and may be manufactured using the present invention. Further note that information handling system 100 can be part of a larger computer system including a network of interconnected systems, and that many of the components in such interconnected systems may include printed circuit boards manufactured according to present invention. Information handling system 100 includes one or more processors 110 coupled to processor interface bus 112. Processor interface bus 112 connects processors 110 to Northbridge 115, which is also known as the Memory Controller Hub (MCH). Northbridge 115 connects to system memory 120 and provides a means for processor(s) 110 to access the system memory. Graphics controller 125 also connects to Northbridge 115. In one embodiment, PCI Express bus 118 connects Northbridge 115 to graphics controller 125. Graphics controller 125 connects to display device 130, such as a computer monitor.

Northbridge 115 and Southbridge 135 connect to each other using bus 119. In one embodiment, the bus is a Direct Media Interface (DMI) bus that transfers data at high speeds in each direction between Northbridge 115 and Southbridge 135. In another embodiment, a Peripheral Component Interconnect (PCI) bus connects the Northbridge and the Southbridge. Southbridge 135, also known as the I/O Controller Hub (ICH) is a chip that generally implements capabilities that operate at slower speeds than the capabilities provided by the Northbridge. Southbridge 135 typically provides various busses used to connect various components. These busses include, for example, PCI and PCI Express busses, an ISA bus, a System Management Bus (SMBus or SMB), and/or a Low Pin Count (LPC) bus. The LPC bus often connects low-bandwidth devices, such as boot ROM 196 and “legacy” I/O devices (using a “super I/O” chip). The “legacy” I/O devices (198) can include, for example, serial and parallel ports, keyboard, mouse, and/or a floppy disk controller. The LPC bus also connects Southbridge 135 to Trusted Platform Module (TPM) 195. Other components often included in Southbridge 135 include a Direct Memory Access (DMA) controller, a Programmable Interrupt Controller (PIC), and a storage device controller, which connects Southbridge 135 to nonvolatile storage device 185, such as a hard disk drive, using bus 184.

ExpressCard 155 is a slot that connects hot-pluggable devices to the information handling system. ExpressCard 155 supports both PCI Express and USB connectivity as it connects to Southbridge 135 using both the Universal Serial Bus (USB) the PCI Express bus. Southbridge 135 includes USB Controller 140 that provides USB connectivity to devices that connect to the USB. These devices include webcam (camera) 150, infrared (IR) receiver 148, keyboard and trackpad 144, and Bluetooth device 146, which provides for wireless personal area networks (PANs). USB Controller 140 also provides USB connectivity to other miscellaneous USB connected devices 142, such as a mouse, removable nonvolatile storage device 145, modems, network cards, ISDN connectors, fax, printers, USB hubs, and many other types of USB connected devices. While removable nonvolatile storage device 145 is shown as a USB-connected device, removable nonvolatile storage device 145 could be connected using a different interface, such as a Firewire interface, etcetera.

Wireless Local Area Network (LAN) device 175 connects to Southbridge 135 via the PCI or PCI Express bus 172. LAN device 175 typically implements one of the IEEE 802.11 standards of over-the-air modulation techniques that all use the same protocol to wireless communicate between information handling system 100 and another computer system or device. Optical storage device 190 connects to Southbridge 135 using Serial ATA (SATA) bus 188. Serial ATA adapters and devices communicate over a high-speed serial link. The Serial ATA bus also connects Southbridge 135 to other forms of storage devices, such as hard disk drives. Audio circuitry 160, such as a sound card, connects to Southbridge 135 via bus 158. Audio circuitry 160 also provides functionality such as audio line-in and optical digital audio in port 162, optical digital output and headphone jack 164, internal speakers 166, and internal microphone 168. Ethernet controller 170 connects to Southbridge 135 using a bus, such as the PCI or PCI Express bus. Ethernet controller 170 connects information handling system 100 to a computer network, such as a Local Area Network (LAN), the Internet, and other public and private computer networks. Luminometer 143 is a luminescence detection device that is capable of detecting luminescence on an object, such as a printed circuit board (PCB). In the embodiment shown, the luminometer is connected to the information handling system using one of the USB connections provided by USB Controller 140. Other embodiments may be utilized in which luminometer 143 is included in the information handling system using a different interface provided by the information handling system.

While FIG. 1 shows one information handling system, an information handling system may take many forms. For example, an information handling system may take the form of a desktop, server, portable, laptop, notebook, or other form factor computer or data processing system. In addition, an information handling system may take other form factors such as a personal digital assistant (PDA), a gaming device, ATM machine, a portable telephone device, a communication device or other devices that include a processor and memory.

The Trusted Platform Module (TPM 195) shown in FIG. 1 and described herein to provide security functions is but one example of a hardware security module (HSM). Therefore, the TPM described and claimed herein includes any type of HSM including, but not limited to, hardware security devices that conform to the Trusted Computing Groups (TCG) standard, and entitled “Trusted Platform Module (TPM) Specification Version 1.2.” The TPM is a hardware security subsystem that may be incorporated into any number of information handling systems, such as those outlined in FIG. 2.

FIG. 2 provides an extension of the information handling system environment shown in FIG. 1 to illustrate that the methods described herein can be performed on a wide variety of information handling systems that operate in a networked environment. Types of information handling systems range from small handheld devices, such as handheld computer/mobile telephone 210 to large mainframe systems, such as mainframe computer 270. Examples of handheld computer 210 include personal digital assistants (PDAs), personal entertainment devices, such as MP3 players, portable televisions, and compact disc players. Other examples of information handling systems include pen, or tablet, computer 220, laptop, or notebook, computer 230, workstation 240, personal computer system 250, and server 260. Other types of information handling systems that are not individually shown in FIG. 2 are represented by information handling system 280. As shown, the various information handling systems can be networked together using computer network 200. Types of computer network that can be used to interconnect the various information handling systems include Local Area Networks (LANs), Wireless Local Area Networks (WLANs), the Internet, the Public Switched Telephone Network (PSTN), other wireless networks, and any other network topology that can be used to interconnect the information handling systems. Many of the information handling systems include nonvolatile data stores, such as hard drives and/or nonvolatile memory. Some of the information handling systems shown in FIG. 2 depicts separate nonvolatile data stores (server 260 utilizes nonvolatile data store 265, mainframe computer 270 utilizes nonvolatile data store 275, and information handling system 280 utilizes nonvolatile data store 285). The nonvolatile data store can be a component that is external to the various information handling systems or can be internal to one of the information handling systems. In addition, removable nonvolatile storage device 145 can be shared among two or more information handling systems using various techniques, such as connecting the removable nonvolatile storage device 145 to a USB port or other connector of the information handling systems.

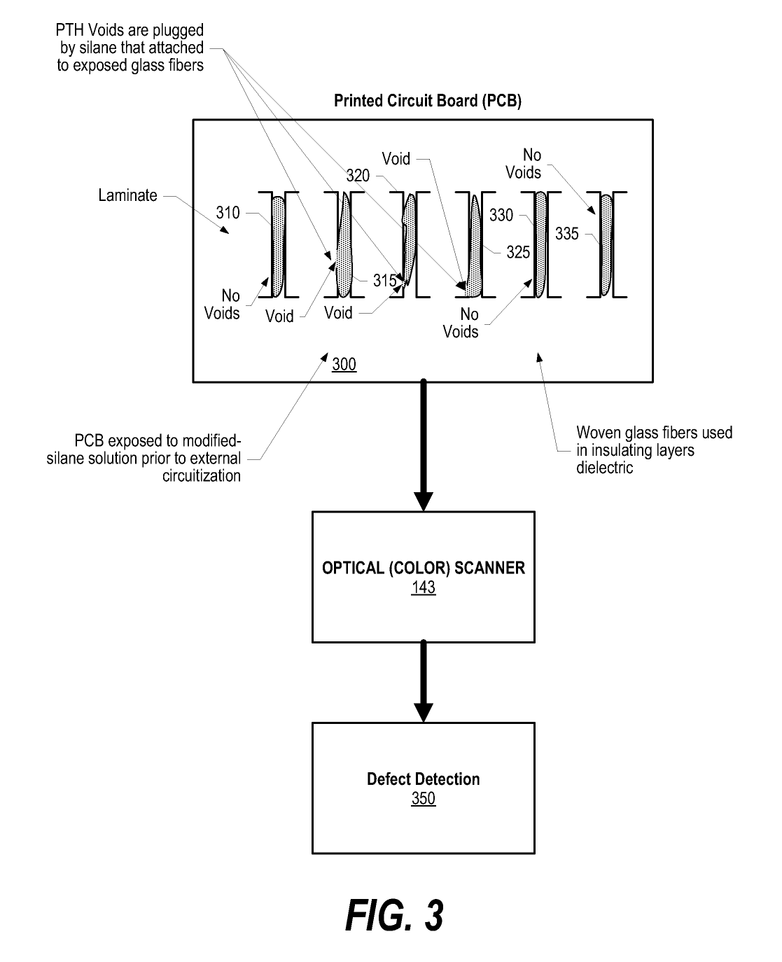

FIG. 3 is a diagram a printed circuit board (PCB) with a variety of plated through hole voids shown in various circuits on the PCB with the PCB being exposed to a modified silane solution that has a luminescence moiety. Printed circuit board 300 is a circuit board with multiple layers including a glass-fiber layer. The glass fiber layer has been exposed to a modified silane solution that has a luminescent moiety that binds to the exposed glass within the printed circuit board laminate. A conductive sheet of material, such as a copper sheet, is laminated onto the outer surface of the PCB from which a number of conductive pathways (310, 315, 320, 325, 330, and 335) are formed on the PCB. In one embodiment, the conductive pathways are formed by etching the conductive sheet to form the pathways.

The PCB is then scanned by luminometer 143 in order to detect any luminescence caused by any exposed glass fiber bundle ends on the PCB. The detection of a luminescence on the surface of the PCB identifies locations of plated-through-hole (PTH-void) defects in the PCB (defect detection 350).

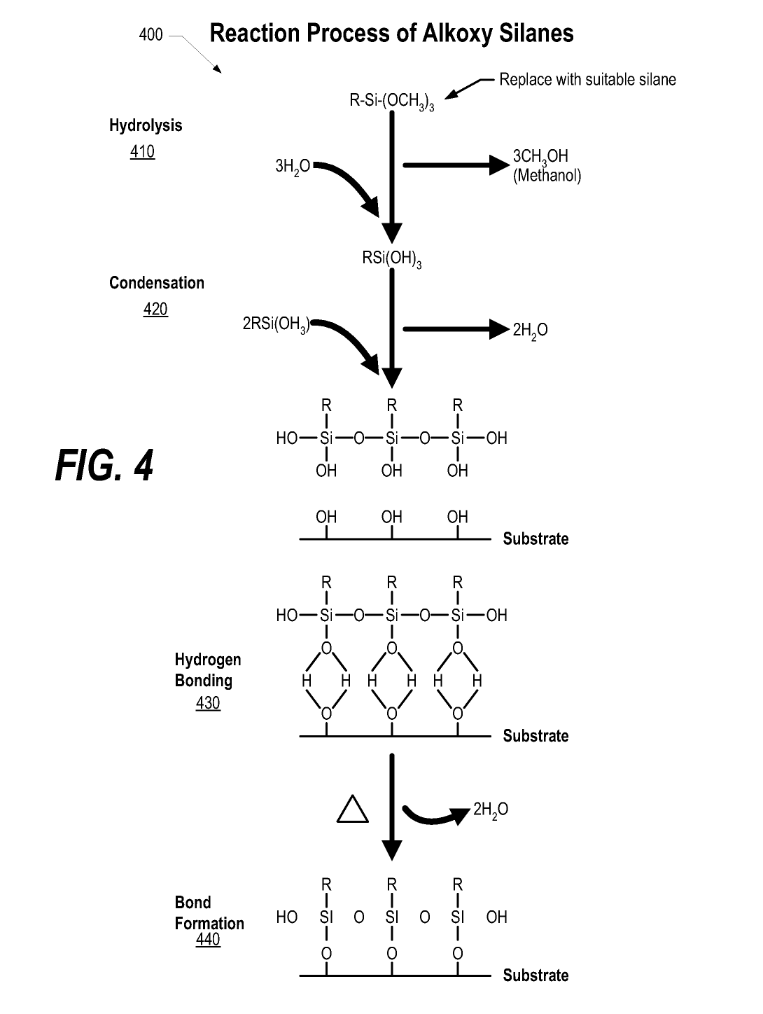

In FIG. 3, the PCB is drilled, desmeared, and plated using conventional techniques. The exposed conductive layer (e.g, a thin copper sheet, etc.) in the PCB is acid etched to remove oxide, rinsed, then coated (optionally) with a corrosion inhibitor, such as benzotriazole (BTA). The BTA coats the exposed copper and prevents subsequent chemisorption of the silane. The board is then subjected to an aqueous silane bath whose parameters (temperature, pH, and silane concentration) are adjusted to deposit a sufficient layer of silane on the exposed glass fiber bundle ends present in the plated-through hole (PTH) void. The silane reacts through the trialkoxy groups with the exposed silanols on the glass to form a siloxane which can be further polymerized to form a crosslinked ‘plug’ in the PTH (see the reaction scheme shown in FIG. 4). Note that a ‘plug’ may be any size, e.g., a complete plug of the PTH, a partial plug of the PTH, or an incomplete plug of the PTH.

One preferred embodiment of the invention uses trialkoxysilanes to form the plugs. There is a wealth of information detailing the coupling reaction of the alkoxy silanes to glass surfaces, so this reaction is well understood. However, other species that chemically bind to glass and that can be polymerized can be used in the invention.

In one embodiment of the invention, colored silanes are used to form the plug. In another embodiment of the invention, a luminescent compound is not used, and the plug is sensed based on the level of transmitted light through the plated-through hole.

FIG. 4 is a reaction scheme showing the modified silane reacting through trialkoxy groups with exposed silanols on the glass to form a siloxane which is polymerized to form a crosslinked plug in the plated-through hole (PTH) voids on the printed circuit board. Reaction scheme 400 includes a number of phases. These phases include hydrolysis phase 410. The hydrolysis phase is followed by condensation phase 420. The condensation phase is followed by hydrogen bonding phase 430 where compounds are bound to the substrate. The hydrogen bonding phase 430 is followed by bond formation phase 440.

In the instant disclosure, R—Si—(OCH₃)₃ in hydrolysis phase 410 of reaction scheme 400 is replaced with one of the representative silanes discussed below. The trialkoxy silane is pre-hydrolyzed via elimination of alcohol (either methanol or ethanol) to form the trihydroxy silane. Depending on the pH, temperature, silane concentration, etc., condensation (phase 420) of the trihydroxy silane results in a pre-polymer which couples to the active glass surface via hydrogen bonding to surface hydroxyl groups. A subsequent thermal bake drives off water to form an Si—O-glass covalent bond. At this phase, the luminescent silane is firmly bound to the glass surface and cannot be easily removed. Unbound silane (in PTHs without voids) can be readily rinsed free of the PTH. Suitable silanes for this process are methyl (1-pyrenyl)dimethylethyl (2-triethylsiloxy)silane and methyl 1(1-pyrenyl)dimethylethyl (1-triethylsiloxy)silane as disclosed in U.S. Pat. No. 4,746,751. Additionally, the photoactive perylenediimide-bridged silsesquioxane disclosed in Chem. Mater. 2005, 17, 2234-2236, shown below, can also be used in this reaction scheme. The aforementioned silanes are examples and the concept of detecting luminescence at a surface location is not limited to the aforementioned silanes. Any alkoxy-substituted silane incorporating a luminescent moiety may be used. The silanes may be deposited from aqueous solution where the trialkoxy groups will condense with surface silanols on the exposed glass fiber to form a siloxane bound to the fiber. Adjustment of the process parameters enables polymerization of the silane and formation of a luminescent, crosslinked gel or ‘plug’. The PCB is subsequently rinsed to remove uncoupled silane from the PTHs. The plugged hole of the PCB can then be detected by applying backlighting inspection techniques or other similar techniques, including use of a luminometer to detect the luminescence at the PCB surface locations of the PTHs.

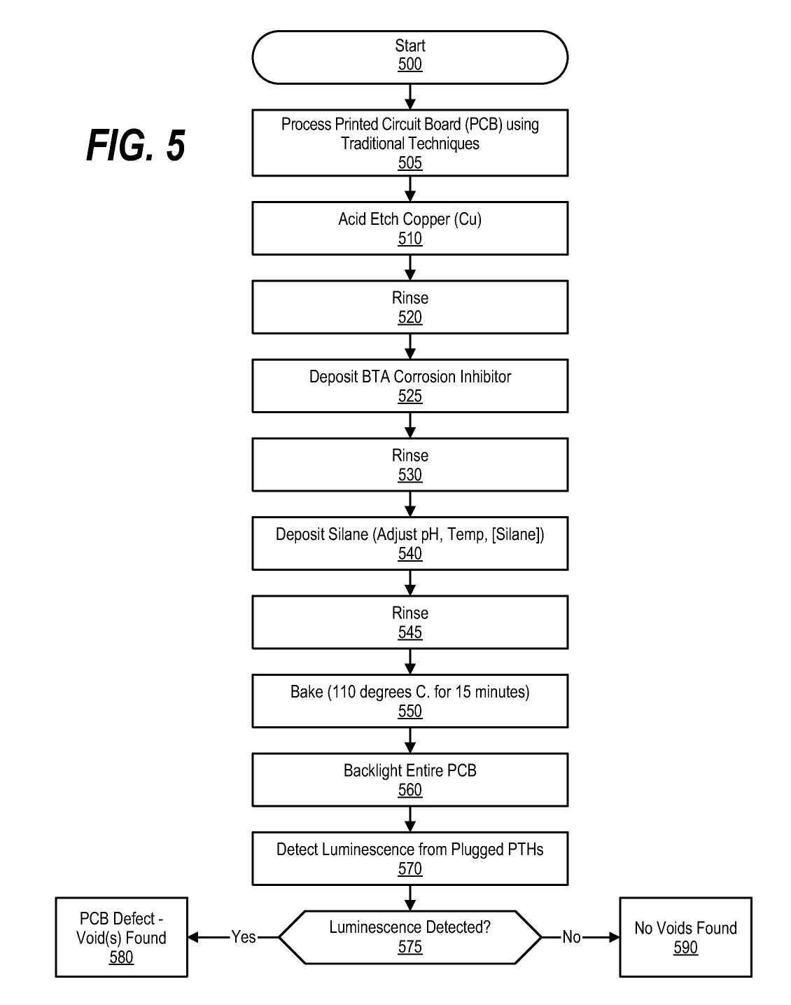

FIG. 5 is a flowchart showing steps taken to detect voids in a PCB that has a been exposed to a modified silane solution with a luminescence moiety as shown in FIG. 3. Processing commences at 500 whereupon, at step 505, the PCB having been exposed to a modified-silane solution bonded to a glass fiber layer of the PCB, with the modified silane solution having a luminescence moiety is processed using traditional techniques. One of these traditional processing steps includes laminating a conductive sheet (e.g., a thin sheet of copper, etc.) onto an outer surface of the PCB. At step 510, the conductive sheet is acid etched to remove oxides. At step 520, the PCB is rinsed. At step 525, in one embodiment, the conductive (e.g., copper) sheet is deposited (coated) with a corrosion inhibitor, such as benzotriazole (BTA). The corrosion inhibitor coats the exposed conductive layer (copper) and prevents subsequent chemisorption of the silane. At step 530, the PCB is rinsed again. At step 540, the PCB is deposited with silane by immersing in an aqueous silane bath whose parameters (temperature, pH, and silane concentration) are adjusted to deposit a sufficient layer of silane on any exposed glass fiber bundle ends that are present in any plated-through-hole defects in the PCB. At step 545, the PCB is rinsed once again. At step 550, the PCB, having been immersed in the silane solution, is baked (e.g., at 110 degrees centigrade for approx. fifteen minutes, etc.). At step 560, the entire PCB is backlit using traditional techniques.

At step 570, luminescence areas on the PCB surface are detected. In one embodiment, the luminescence is detected using a luminometer that is connected to an information handling system. In one embodiment, the luminescence areas are detected manually (visually) by an operator viewing the backlit PCB. A decision is made as to whether luminescence is detected at a surface location of the PCB (decision 575). If luminescence is detected at one or more surface locations, then decision 575 branches to the “yes” branch whereupon, at step 580, the PCB is noted as being defective due to the presence of one or more plated-through-hole defects. On the other hand, if no luminescence is detected, then decision 575 branches to the “no” branch whereupon, at step 590, the PCB is noted as not having any plated-through-hole defects.

While particular embodiments of the present disclosure have been shown and described, it will be obvious to those skilled in the art that, based upon the teachings herein, that changes and modifications may be made without departing from this disclosure and its broader aspects. Therefore, the appended claims are to encompass within their scope all such changes and modifications as are within the true spirit and scope of this disclosure. Furthermore, it is to be understood that the disclosure is solely defined by the appended claims. It will be understood by those with skill in the art that if a specific number of an introduced claim element is intended, such intent will be explicitly recited in the claim, and in the absence of such recitation no such limitation is present. For non-limiting example, as an aid to understanding, the following appended claims contain usage of the introductory phrases “at least one” and “one or more” to introduce claim elements. However, the use of such phrases should not be construed to imply that the introduction of a claim element by the indefinite articles “a” or “an” limits any particular claim containing such introduced claim element to inventions containing only one such element, even when the same claim includes the introductory phrases “one or more” or “at least one” and indefinite articles such as “a” or “an”; the same holds true for the use in the claims of definite articles.

1. A method comprising:
exposing a printed circuit board to a modified-silane solution, wherein the modified-silane solution has a luminescent moiety, and wherein the modified-silane solution binds to exposed glass within a laminate of the printed circuit board; and
identifying a plated-through hole defect in the printed circuit board, wherein the identifying further comprises:
detecting a luminescence at a surface location of the printed circuit board, wherein the surface location corresponds to the plated-through hole defect.

2. The method of claim 1 wherein the detecting further comprises:
backlighting the printed circuit board using a light source, wherein the backlighting reveals the luminescence at the surface location.

3. The method of claim 2 wherein the light source has a wavelength that excites the luminescent moiety of the bound modified-silane solution.

4. The method of claim 1 wherein the modified-silane solution couples to exposed glass fiber bundle ends present in the plated-through hole.

5. The method of claim 1 wherein the modified-silane solution includes a trihydroxy silane solution, the method further comprising:
condensing the trihydroxy silane, the condensing resulting in a pre-polymer that bonds to the exposed glass surface; and
after the condensing, bonding the pre-polymer with the exposed glass surface by thermally baking the printed circuit board.

6. The method of claim 1 further comprising:
prior to the exposing:
plating the printed circuit board with a copper film;
etching the plated printed circuit board in an acid, the etching resulting in a removal of oxide from the plated printed circuit board;
applying a first rinse of the plated printed circuit board, and
coating the rinsed plated circuit board with a corrosion inhibitor.

7. The method of claim 6 wherein the corrosion inhibitor is a BTA corrosion inhibitor, wherein the method further comprises:
applying a second rinse of the printed circuit board after the coating, wherein the printed circuit board is exposed to the modified-silane solution after the second rinse;
thermally baking the printed circuit board after the printed circuit board has been exposed to the modified-silane solution; and
after the baking, backlighting the printed circuit board using a light source, wherein the light source has a wavelength that excites the luminescent moiety of the bound modified-silane solution, and wherein the backlighting reveals the luminescence at the surface location.

8. A product made by a method comprising:
exposing a printed circuit board to a modified-silane solution, wherein the modified-silane solution has a luminescent moiety, and wherein the modified-silane solution binds to exposed glass within a laminate of the printed circuit board.

9. The product of claim 8, wherein the method further comprises:
identifying a plated-through hole defect in the printed circuit board, wherein the identifying further comprises:
detecting a luminescence at a surface location of the printed circuit board, wherein the surface location corresponds to the plated-through hole defect.

10. The product of claim 9 wherein the detecting further comprises:
backlighting the printed circuit board using a light source, wherein the backlighting reveals the luminescence at the surface location.

11. The product of claim 10 wherein the light source has a wavelength that excites the luminescent moiety of the bound modified-silane solution.

12. The product of claim 8 wherein the modified-silane solution couples to exposed glass fiber bundle ends present in a plated-through hole.

13. The product of claim 8 wherein the modified-silane solution includes a trihydroxy silane solution, the method further comprising:
condensing the trihydroxy silane, the condensing resulting in a pre-polymer that bonds to the exposed glass surface; and
after the condensing, bonding the pre-polymer with the exposed glass surface by thermally baking the printed circuit board.

14. The product of claim 8 further comprising:
prior to the exposing:
plating the printed circuit board with a copper film;
etching the plated printed circuit board in an acid, the etching resulting in a removal of oxide from the plated printed circuit board;
applying a first rinse of the plated printed circuit board, and
coating the rinsed plated circuit board with a corrosion inhibitor.

15. The product of claim 14 wherein the corrosion inhibitor is a BTA corrosion inhibitor, wherein the method further comprises:
applying a second rinse of the printed circuit board after the coating, wherein the printed circuit board is exposed to the modified-silane solution after the second rinse;
thermally baking the printed circuit board after the printed circuit board has been exposed to the modified-silane solution; and
after the baking, backlighting the printed circuit board using a light source, wherein the light source has a wavelength that excites the luminescent moiety of the bound modified-silane solution, and wherein the backlighting reveals a luminescence at the surface location.

16. An information handling system comprising:
one or more processors;
a memory coupled to at least one of the processors;
an luminometer accessible by at least one of the processors, wherein the luminometer detects luminescence; and;
a set of computer program instructions stored in the memory and executed by at least one of the processors in order to perform actions of:
detecting, at the luminometer, a luminescence at a surface location of a printed circuit board, wherein the surface location corresponds to a plated-through hole defect in the printed circuit board, wherein the printed circuit board is has been exposed to a modified-silane solution, wherein the modified-silane solution has a luminescent moiety, and wherein the modified-silane solution binds to exposed glass within a laminate of the printed circuit board.

17. The information handling system of claim 16 wherein the printed circuit board is backlit during the detecting using a light source, and wherein the backlighting reveals the luminescence at the surface location.

18. The information handling system of claim 17 wherein the light source has a wavelength that excites the luminescent moiety of the bound modified-silane solution.

19. The information handling system of claim 16 wherein the modified-silane solution couples to exposed glass fiber bundle ends present in the plated-through hole.

20. The information handling system of claim 16 wherein the modified-silane solution includes a trihydroxy silane solution that has been condensed to a pre-polymer bound to the exposed glass surface, and wherein the printed circuit board was thermally baked to bind the pre-polymer with the exposed glass surface.
